(19) United States
(12) Patent Application Publication
(10) Pub. No.: US 2017/0069490 A1
(43) Pub. Date: Mar. 9, 2017

(54) ATOMIC LAYER DEPOSITION OF GERMANIUM OR GERMANIUM OXIDE

(71) Applicant: Picosun Oy, Espoo (FI)

(72) Inventor: Wei-Min LI, Espoo (FI)

(21) Appl. No.: 15/123,130

(22) PCT Filed: Mar. 4, 2014
(86) PCT No.: PCT/FI2014/050155

§ 371 Date: Sep. 1, 2016

(51) Int. Cl. H01L 21/02; C23C 16/18; C23C 16/08; C23C 16/455; C23C 16/40

(52) U.S. Cl. CPC H01L 21/02532; H01L 21/02381; H01L 21/02387; H01L 21/02422; H01L 21/0262; H01L 21/02205; H01L 21/02112; H01L 21/02274; H01L 21/0228; C23C 16/45536; C23C 16/407; C23C 16/08; C23C 16/18

(57) ABSTRACT

A process of depositing germanium on a substrate includes sequentially exposing in at least one deposition cycle the substrate inside a chamber with a Ge-containing precursor and a reducing or oxidizing precursor.

### FIELD

The aspects of the disclosed embodiments relate to depositing germanium and germanium oxide with atomic layer deposition (ALD) on substrates.

### BACKGROUND

Atomic Layer Epitaxy (ALE) method was invented by Dr. Tuomo Suntola in the early 1970's. Another generic name for the method is Atomic Layer Deposition (ALD) and it is nowadays used instead of ALE. ALD is a special chemical deposition method based on the sequential introduction of at least two reactive precursor species to at least one substrate.

A basic ALD deposition cycle consists of four sequential steps: pulse A, purge A, pulse B and purge B. Pulse A typically consists of metal precursor vapor and pulse B of nitrogen or oxygen precursor vapor. Inactive gas, such as nitrogen or argon, and a vacuum pump are used for purging gaseous reaction by-products and the residual reactant molecules from the reaction space. A deposition sequence contains at least one deposition cycle. Deposition cycles are repeated until the deposition sequence has produced a thin film of desired thickness.

Precursor species form a chemical bond to reactive sites of the heated surfaces through chemisorption. Reaction conditions are typically arranged in such a way that no more than a molecular or atomic monolayer of a solid material forms on the surfaces during one precursor pulse. Thus, the growth process is self-terminating, i.e. saturative growth. For example, the first precursor can include ligands that remain attached to the adsorbed species and saturate the surface, which prevents further chemisorption. Reaction space temperature is maintained above condensation temperatures and below thermal decomposition temperatures of the utilized precursors such that the precursor molecule species chemisorb on the substrate(s) essentially intact. This chemisorption step is typically followed by a first purge step (purge A) wherein the excess first precursor and possible reaction by-products are removed from the reaction space. Second precursor vapor is then introduced into the reaction space. Second precursor molecules typically react with the adsorbed species of the first precursor molecules, thereby forming the desired thin film material. This growth terminates once the entire amount of the adsorbed first precursor has been consumed. The excess of second precursor vapor and possible reaction by-product vapors are then removed by a second purge step (purge B). The cycle is then repeated until the film has grown to a desired thickness.

Germanium is a promising material for use in semiconductor and optoelectronic devices because it has very high mobility and generally very good transport properties. Compared to silicon or gallium, germanium is much more ordered and has better mobility, making it useful e.g. as a gate oxide in silicon or germanium based transistors.

Despite the great interest of e.g. the semiconductor industry in Ge-deposition, ALD processes for depositing germanium have not been successful. Thus, there still remains a need for industrially applicable methods for depositing germanium and germanium oxide layers on various substrates.

### SUMMARY

According to a first aspect of the disclosed embodiments there is provided a process of depositing germanium on a substrate, comprising sequentially exposing in at least one deposition cycle the substrate inside a chamber with a Ge-containing precursor and a reducing or oxidizing precursor.

According to certain example embodiments there is provideds a method of depositing elemental germanium (Ge) or germanium dioxide (GeO₂) on substrates, the deposition method comprising sequentially exposing in at least one deposition cycle a substrate inside a deposition chamber with germanium precursor and reducing or oxidizing gas, respectively.

In certain example embodiments the sequential exposure of the substrate comprises running a deposition sequence comprising at least one deposition cycle of Ge precursor pulse; a purge with an inert gas; reducing or oxidizing pulse; and a purge with an inert gas. Accordingly, in certain example embodiments, said at least one deposition cycle comprises:

a. Ge-containing precursor pulse;

b. Purge with an inert gas;

c. Reducing or oxidizing pulse; and

d. Purge with an inert gas.

In certain example embodiments, in step c the reducing precursor is selected from the group consisting of H₂ and hydrogen plasma.

In certain example embodiments, H₂ is used in step c of the deposition cycle as the reducing pulse in an amount of about 4-100%, preferably about 5-50%, most preferably about 15% (volume/volume) in a mixture with an inert gas.

In certain example embodiments, in step c the oxidizing precursor is selected from O₂, O₃, H₂O₂, oxygen plasma, water and water plasma.

The sequential self-saturating surface reactions in ALD produce the desired coating on the substrate inside the deposition chamber. Accordingly, in certain example embodiments, the substrate is coated by using ALD so that essentially all surfaces of the substrate are exposed to the reactants and coated.

The process according to the disclosed embodiments for depositing substrates with germanium or germanium oxide can be carried out with the apparatus described in WO 2009/144371.

According to a second aspect of the disclosed embodiments there is provided use of tetrakis(dimethylamino)Ge in atomic layer deposition.

In certain example embodiments, said atomic layer deposition is for depositing a silicon substrate.

According to a third aspect of the disclosed embodiments there is provided a Ge deposited article manufactured by coating an undeposited article as a substrate by the process according to the first aspect or its embodiments.

Different non-binding example aspects and embodiments of the present disclosure have been illustrated above. The above embodiments are used merely to explain selected aspects or steps that may be utilized in implementations of the disclosed embodiments. Some embodiments may be presented only with reference to certain example aspects of the disclosed embodiments. It should be appreciated that corresponding embodiments may apply to other example aspects as well. Any appropriate combinations of the embodiments may be formed.

Accordingly, the following detailed description is not to be taken in a limiting sense, and the scope of the present disclosed embodiments are defined only by the appended claims.

### BRIEF DESCRIPTION OF THE FIGURES

FIG. 1 is an XRD graph providing data on deposition using the deposition method according to the disclosed embodiments.

### DETAILED DESCRIPTION

In the following description, Atomic Layer Deposition (ALD) technology is used to make Ge or GeO₂ coatings on substrates. The basic principles of the ALD deposition are known to a skilled person. As discussed above, ALD is a special chemical deposition method based on the sequential introduction of at least two reactive precursor species to at least one substrate. The method according to the disclosed embodiments is equally applicable to coating more than one substrate of same or different type. The at least one substrate is exposed to temporally separated precursor pulses in a reaction chamber to deposit material on the substrate surfaces by sequential self-saturating surface reactions. In the context of this application, the term ALD comprises all applicable ALD based techniques and any equivalent or closely related technologies, such as, for example MLD (Molecular Layer Deposition) technique.

A basic ALD deposition cycle consists of four sequential steps: pulse A, purge A, pulse B and purge B. Pulse A consists of a first precursor vapor and pulse B of another precursor vapor. Inactive gas and a vacuum pump are typically used for purging gaseous reaction by-products and the residual reactant molecules from the reaction space during purge A and purge B. A deposition sequence comprises at least one deposition cycle. Deposition cycles are repeated until the deposition sequence has produced a thin film or coating of desired thickness.

The ALD process according to certain example embodiments is further illustrated by the following description. Ge or GeO₂ is grown on a substrate from heated Ge precursor and reducing/oxidizing precursor. A heated Ge precursor source is heated to a selected source temperature to create sufficient Ge precursor vapor pressure to be transferrable to the reaction chamber at about 0.1-10 Torr. In some embodiments which use heat-sensitive precursors or substrates it is advantageous to evaporate the precursor at temperatures as low as possible to avoid unnecessary decomposition of precursors or substrates, while still generating a sufficiently big precursor vapor dosage for covering the whole substrate surface. A skilled person is able to adjust the required temperature according to the particular precursor and substrate.

An advantage of volatile precursors at low pressure is that low pressure increases the diffusion speed of gas molecules and helps to recover the equilibrium vapor pressure as fast as possible.

In certain example embodiments, the first precursor is selected from the group consisting of tetrakis(dimethylamino)Ge and derivatives of germanium amidinates, alkyl germanium; alky halide germanium; tetramethyl-Ge, (CH₃)₃GeCl; germanium beta-diketonates, germanium acetyl acetonates, and germanium halides. The second precursor is selected from the group consisting of H₂, hydrogen plasma, and O₂, O₃, H₂O₂, oxygen plasma, water and water plasma.

In certain example embodiments, tetrakis(dimethylamino)Ge, having the chemical formula [(CH₃)₂N]₄Ge, is used in the atomic layer deposition method.

In certain example embodiments, tetrakis(dimethylamino)Ge is used as the first precursor and the second precursor is O₃. The following deposition reaction is obtained:

[(CH₃)₂N]₄Ge+O₃→GeO₂+by products

In certain example embodiments, tetrakis(dimethylamino)Ge, having the chemical formula [(CH₃)₂N]₄Ge, is used as the first precursor and the second precursor is H₂.

The following deposition reaction is obtained:

[(CH₃)₂N]₄Ge+H*→Ge+by products

H* refers to radicals, plasma and other energetic species.

The amount of hydrogen as the second precursor in the process may vary. Suitable amounts of H₂ in this respect are 4%-100% based on the volume of hydrogen in an inert carrier gas. The amount of H₂ may be about 4%-90%, about 4%-80%, about 4%-70%, about 4%-60%, about 4%-50%, about 4%-40%, about 4%-30%, about 4%-20%, about 4%-10%, about 10%-90%, about 10%-80%, about 10%-70%, about 10%-60%, about 10%-50%, about 10%-40%, about 10%-30%, or about 10-20%, such as about 95%, 90%, 85%, 80%, 75%, 70%, 65%, 60%, 55%, 50%, 45%, 40%, 35%, 30%, 25%, 20%, 15%, 10%, 5% or 4%. Suitably, the inert carrier gas may be N₂ or Ar. When hydrogen plasma is used, the inert gas is preferably Ar.

The formation of the deposited layer can be verified e.g. by X-ray diffractometry (XRD), X-ray photon spectroscopy (XPS), or X-ray reflection (XRR).

The deposition process may be carried out at a temperature in the range of about 300° C.-about 800° C., such as at about 800° C., 750° C., 700° C., 650° C., 600° C., 550° C., 500° C., 450° C., 440° C., 430° C., 420° C., 410° C., 400° C., 390° C., 380° C., 370° C., 360° C., 350° C., 340° C., 330° C., 320° C., 310 or 300° C. Suitably lower temperatures are preferred in which the risk of decomposing the precursor is lower.

The following embodiments are provided:

### Embodiment 1

A process of depositing germanium on a substrate comprising sequentially exposing in at least one deposition cycle the substrate inside a chamber with a Ge-containing precursor and a reducing or oxidizing precursor.

### Embodiment 2

The process according to embodiment 1, wherein the at least one deposition cycle comprises:

a. Ge containing precursor pulse;

b. Purge with an inert gas;

c. Reducing or oxidizing pulse; and

d. Purge with an inert gas.

### Embodiment 3

The process according to embodiment 1 or 2, wherein in step c the reducing precursor is selected from the group consisting of H₂ and hydrogen plasma.

### Embodiment 4

The process according to any one of embodiments 1-3, wherein H₂ is used in the step c of the deposition cycle as the reducing pulse in an amount of about 4-100%, preferably about 5-50%, most preferably about 15% (volume/volume) in a mixture with an inert gas.

### Embodiment 5

The process according to embodiment 1 or 2, wherein in the step c the oxidizing precursor is selected from O₂, O₃, H₂O₂, oxygen plasma, water and water plasma.

### Embodiment 6

The process according to any one of embodiments 1-5, wherein the deposition cycle is carried out at a temperature of about 50° C.-about 800° C., preferably at about 100° C.-about 500° C., more preferably at about 300° C.-about 400° C., most preferably at about 350° C.

### Embodiment 7

The process according to any one of embodiments 1-6, wherein the inert gas is nitrogen or argon, and the inert gas is argon when a plasma precursor is used.

### Embodiment 8

The process according to any one of embodiments 1-7, wherein the Ge-containing precursor has a volatility of at least 1 hPa at temperature a range of from room temperature to 200° C.

### Embodiment 9

The process according to any one of embodiments 1-8, wherein the Ge-containing precursor is selected from the group consisting of alkyl germanium, alkylamine germanium, tetrakis(dimethylamine) germanium, diketonate germanium, germanium halides, and germanium alchoxide.

### Embodiment 10

The process according to any one of embodiments 1-9, wherein the substrate is a silicon substrate, germanium substrate, III-V semiconductor, silicon oxide, or germanium oxide substrate, or a substrate based on inorganic and organic/polymer materials.

### Embodiment 11

The process according to any one of embodiments 1-10, wherein the process is based on self-saturating surface reactions.

### Embodiment 12

The process according to any one of embodiments 1-11, wherein the deposition cycle is repeated until the deposited layer has a thickness of 10-100 nm.

### Embodiment 13

Use of tetrakis(dimethylamino)Ge in atomic layer deposition.

### Embodiment 14

The use according to embodiment 13, wherein said atomic layer deposition is for depositing a silicon substrate.

### Embodiment 15

The use according to any one of embodiments 13-14 wherein the use comprises depositing Ge or GeO₂.

### Embodiment 16

A Ge or GeO₂ deposited article manufactured by coating an undeposited article as a substrate by the process according to any one of embodiments 1-12.

### EXAMPLES

The following examples are provided to illustrate various aspects of the disclosed embodiments. They are not intended to limit the disclosed embodiments, which is defined by the accompanying claims.

### Example 1

### Deposition of Elemental Germanium

Tetrakis(dimethylamino)germanium and H₂ were used as precursors to deposit Ge on Si substrate.

The following deposition cycle at 350° C. was used to run 1000 cycles. Suitable line pressure for precursor source line is 1-10 torr, reaction vessel pressure 1-10 torr, inert carrier gas flow rate 30-300 sccm:

1s[(CH₃)₂N]₄Ge/2sN₂/1s15% H₂ in N₂/1sN₂

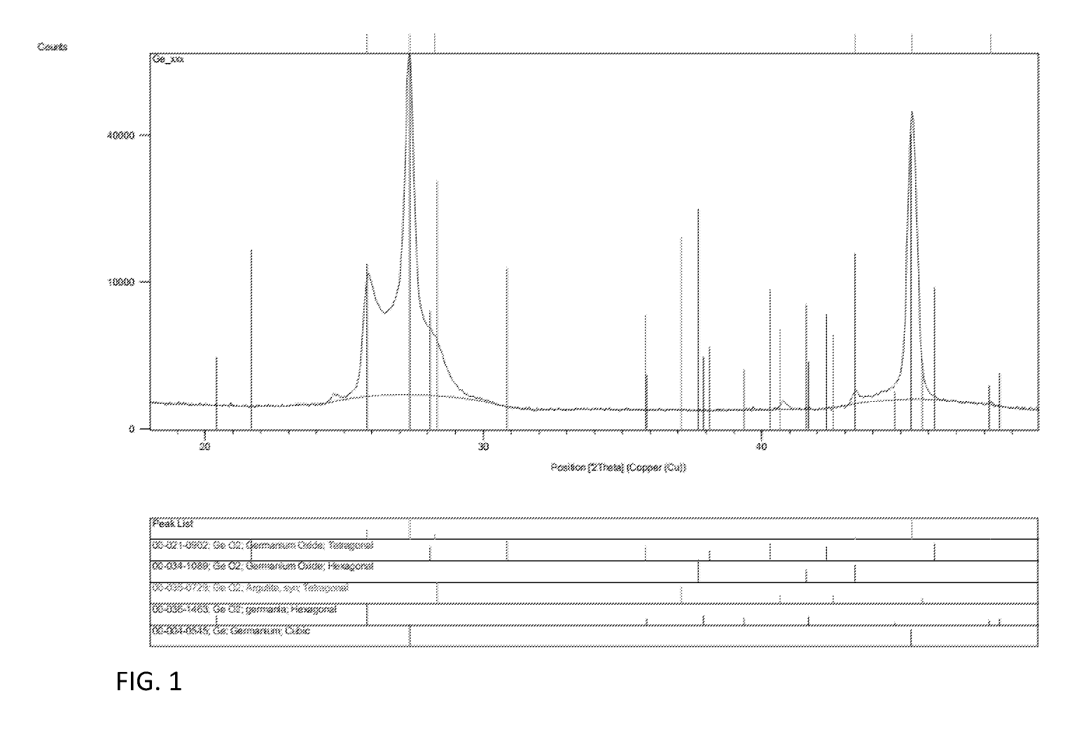

As revealed by the XRD analysis shown in FIG. 1, Ge film was deposited on the Si substrate. The small amount of Ge oxide seen in the analysis is due to oxidation of the deposited Ge layer caused by oxygen present in the atmosphere.

Instead of tetrakis(dimethylamino)Ge, one or more of the following Ge-containing precursors may be used to deposit Ge or GeO₂ on substrates: alkyl germanium; alky halide germanium; alkyl germanium; alkyl halide germanium; tetramethyl-Ge, (CH₃)₃GeCl; germanium beta-deketonates; germanium acetyl acetonates: and germanium amidinates. Suitably, the deposition parameters, such as temperature and, reaction pressure, precursor line pressure are adjusted to be compatible with the particular precursor.

The above deposition method can also be carried out at various temperatures listed above as long as the temperature is below decomposition temperature of the precursors.

### Example 2

### Deposition of Germanium Dioxide

Tetrakis(dimethylamino)germanium and O₃ were used as precursors to deposit GeO₂ on a Si substrate.

The following deposition cycle at 350° C. was used to run 1000 cycles:

1s[(CH₃)₂N]₄Ge/2sN₂/1sO₃/1sN₂

The substrate was coated with a Ge oxide film.

Instead of tetrakis(dimethylamino)Ge one or more of the following Ge-containing precursors may be used: alkyl germanium; alky halide germanium; alkyl germanium; alkyl halide germanium; tetramethyl-Ge, (CH₃)₃GeCl; germanium beta-diketonates; germanium acetyl acetonates: and germanium amidinates.

The above deposition method can also be carried out at various temperatures below decomposition temperature of the precursors.

1. A process of depositing germanium on a substrate comprising sequentially exposing in at least one deposition cycle the substrate inside a chamber with a Ge-containing precursor and a reducing or oxidizing precursor.

2. The process according to claim 1, wherein the at least one deposition cycle comprises:
a. Ge containing precursor pulse;
b. Purge with an inert gas;
c. Reducing or oxidizing pulse; and
d. Purge with an inert gas.

3. The process according to claim 1, wherein in step c. the reducing precursor is selected from the group consisting of H₂ and hydrogen plasma.

4. The process according to claim 1, wherein H₂ is used in the step c. of the deposition cycle as the reducing pulse in an amount of about 4-100% (vol./vol.), preferably about 5-50% (vol./vol.), most preferably about 15% (vol./vol.) in a mixture with an inert gas.

5. The process according to claim 1, wherein in the step c. the oxidizing precursor is selected from O₂, O₃, H₂O₂, oxygen plasma, water and water plasma.

6. The process according to claim 1, wherein the deposition cycle is carried out at a temperature of about 50° C.-about 800° C., preferably at about 100° C.-about 500° C., more preferably at about 300° C.-about 400° C., and most preferably at about 350° C.

7. The process according to claim 1, wherein the inert gas is nitrogen or argon, and the inert gas is argon when a plasma precursor is used.

8. The process according to claim 1, wherein the Ge-containing precursor has a volatility of at least 1 hPa at a temperature range of from room temperature to 200° C.

9. The process according to claim 1, wherein the Ge-containing precursor is selected from the group consisting of alkyl germanium, alkylamine germanium, tetrakis(dimethylamine) germanium, diketonate germanium, germanium halides, and germanium alchoxide.

10. The process according to claim 1, wherein the substrate is a silicon substrate, germanium substrate, III-V semiconductor, silicon oxide, or germanium oxide substrate, or a substrate based on inorganic and organic/polymer materials.

11. The process according to claim 1, wherein the process is based on self-saturating surface reactions.

12. The process according to claim 1, wherein the deposition cycle is repeated until the deposited layer has a thickness of 10-100 nm.

13. Use of tetrakis(dimethylamino) germanium in atomic layer deposition.

14. The use according to claim 13, wherein said atomic layer deposition is for depositing a silicon substrate.

15. A Ge deposited article manufactured by coating an undeposited article as a substrate by the process according to claim 1.
